(19) United States
(12) Patent Application Publication
(10) Pub. No.: US 2026/0163333 A1
(43) Pub. Date: Jun. 11, 2026

(54) SEMICONDUCTOR LASER WITH INTERRUPTED GROOVES

(71) Applicant: Excelitas Canada, Inc., Vaudreuil-Dorion (CA)

(72) Inventors: Sasa Ristic, Vaudreuil-Dorion (CA); Dumitru Grigore Huminic, Vaudreuil-Dorion (CA); Sylvain Laframboise, Vaudreuil-Dorion (CA)

(21) Appl. No.: 19/415,093

(22) Filed: Dec. 10, 2025

Related U.S. Application Data
(60) Provisional application No. 63/730,350, filed on Dec. 10, 2024.

(51) Int. Cl. H01S 5/22; H01S 5/02345; H01S 5/24

(52) U.S. Cl. CPC H01S 5/22; H01S 5/02345; H01S 5/24

(57) ABSTRACT

The inventors have developed technology to facilitate improved performance of broad area lasers and improved wire bonding configurations, which are described herein. As an example, broad area lasers include a waveguide ridge positioned on a semiconductor between adjacent grooves. The inclusion of horizontal ridges to transect the grooves at the exit facet and/or along the length of the waveguide ridge of the laser to connect the semiconductor waveguide ridge with the adjoining substrate may improve the power output and/or quality of the beam profile of the broad area semiconductor laser.

### CROSS REFERENCE TO RELATED APPLICATIONS

This application claims the benefit of priority under 35 U.S.C. § 119(e) to U.S. Provisional Patent Application Ser. No. “63/730,350,” filed on Dec. 10, 2024, and entitled, “SEMICONDUCTOR LASER WITH INTERRUPTED GROOVES,” under Attorney Docket No. E0643.70020US00, which is hereby incorporated by referenced herein in its entirety.

### BACKGROUND

Broad area lasers produce a large laser beam with multi-mode emission from the laser. Given the emission profiles of broad area lasers, they may provide high-power pulsed laser outputs for applications in communications, material processing, medical applications, remoting and remote sensing. For example, self-navigation technologies may rely on broad area lasers for generating optical signals for transmitting information or sensing.

### SUMMARY

Some aspects of the present technology are directed to an integrated semiconductor laser comprising: a semiconductor substrate including a plurality of semiconductor layers having a transverse axis aligned with an optical axis of the integrated semiconductor laser, the plurality of semiconductor layers including at least one active layer; a waveguide ridge disposed through the plurality of semiconductor layers and extending along the transverse axis between a front facet and a back facet of the integrated semiconductor laser; a plurality of grooves disposed on opposing sides of the waveguide ridge, wherein the plurality of grooves is elongated along the transverse axis; and at least one lateral ridge extending across at least one of the plurality of grooves.

In some embodiments, a first lateral ridge of the at least one lateral ridge is configured at an end facet of the integrated semiconductor laser such that a surface of the end facet is smooth.

In some embodiments, a second lateral ridge of the at least one lateral ridge is configured at a second end facet such that a surface on each end facet of the integrated semiconductor laser is smooth.

In some embodiments, a first lateral ridge of the at least one lateral ridge is configured to intersect a middle portion of the waveguide ridge.

In some embodiments, the first lateral ridge transects a first groove of the plurality of grooves on a first side of the waveguide ridge and the first lateral ridge further transects a second groove of the plurality of grooves on a second side of the waveguide ridge.

In some embodiments, a second lateral ridge of the at least one lateral ridge transects the first groove, such that the first lateral ridge and second lateral ridge divide the first groove into three shorter grooves.

In some embodiments, a metal trace is disposed on a top surface of the first lateral ridge, and the metal trace is separated from a top semiconductor layer of the first lateral ridge by an insulating layer.

In some embodiments, the integrated semiconductor laser further comprises a first wire bonding pad and a second wire bonding pad, wherein the second wire bonding pad is separated from the first wire bonding pad by the waveguide ridge and the plurality of grooves.

In some embodiments, the first wire bonding pad comprises a metal pad separated from a top semiconductor layer of the integrated semiconductor laser by an insulating layer.

In some embodiments, the first wire bonding pad and the metal trace are further configured to inject carriers into the waveguide ridge when a current is applied to the first wire bonding pad.

In some embodiments, the at least one lateral ridge is formed of a material having approximately a same refractive index as a material of which the waveguide ridge is formed.

In some embodiments, the at least one lateral ridge is formed of a same material as that which the waveguide ridge is formed.

In some embodiments, the plurality of semiconductor layers comprises additional active layers, and the total number of active layers, separated by tunneling junctions, for the integrated semiconductor laser is between 2 and 10 active layers.

In some embodiments, the plurality of semiconductor layers are epitaxial layers.

Some aspects of the present technology are directed to an integrated semiconductor laser comprising: a semiconductor substrate including a plurality of semiconductor layers having a transverse axis aligned with an optical axis of the integrated semiconductor laser, the plurality of semiconductor layers including at least one active layer; a waveguide ridge disposed through the plurality of semiconductor layers and extending along the transverse axis between a front facet and a back facet of the integrated semiconductor laser; a plurality of grooves disposed on opposing sides of the waveguide ridge, wherein the plurality of grooves is elongated along the transverse axis and has a first width; and a plurality of linking grooves that have a width smaller than the first width connecting grooves on a same side of the waveguide ridge.

In some embodiments, the integrated semiconductor laser further comprises a wire bond pad disposed on top of the waveguide ridge.

Some aspects of the present technology are directed to an integrated semiconductor laser comprising: a semiconductor substrate including a plurality of semiconductor layers having a transverse axis aligned with an optical axis of the integrated semiconductor laser, the plurality of semiconductor layers including at least one active layer; a waveguide ridge disposed through the plurality of semiconductor layers and extending along the transverse axis between a front facet and a back facet of the integrated semiconductor laser; and a plurality of grooves disposed on opposing sides of the waveguide ridge, wherein the plurality of grooves is elongated along the transverse axis, and optical confinement of the waveguide ridge by the plurality of grooves varies along the transverse axis.

In some embodiments, the optical confinement of the waveguide ridge by the plurality of grooves is varied by a lateral ridge capping an end of the at least one of the plurality of grooves.

In some embodiments, the plurality of grooves have a first width and wherein the optical confinement of the waveguide ridge by the plurality of grooves is varied by a portion of the groove that has a width smaller than the first width.

### BRIEF DESCRIPTION OF THE DRAWINGS

FIG. 1A shows an example semiconductor laser with interrupted grooves, in accordance with some embodiments of the technology described herein.

FIG. 1B shows a top-down schematic of an asymmetric ridge configuration, in accordance with some embodiments of the technology described herein.

FIG. 1C shows a top-down schematic of a second asymmetric ridge configuration, in accordance with some embodiments of the technology described herein.

FIG. 1D shows a top-down schematic of a third asymmetric ridge configuration, in accordance with some embodiments of the technology described herein.

FIG. 1E shows a top-down schematic of a width-modulated groove, in accordance with some embodiments of the technology described herein.

FIG. 1F shows a cross-sectional view of semiconductor laser 100 through plane I, shown in FIG. 1A.

FIG. 1G shows a perspective view of lateral ridge 110 of semiconductor laser 100, in accordance with some embodiments of the technology described herein.

FIG. 2A shows a top-down view of a wafer with examples of semiconductor lasers with interrupted grooves, in accordance with some embodiments of the technology described herein.

FIG. 2B shows a top-down view of a wafer with modulated grooves, in accordance with some embodiments of the technology described herein.

FIG. 3 shows an example of the power output enhancement induced by horizontal ridges across the grooves at the exit facet, in accordance with some embodiments of the technology described herein.

FIG. 4 shows an example of changes to the beam profile for a laser by including horizontal ridges across the grooves at the exit facet, in accordance with some embodiments of the technology described herein.

FIG. 5A shows an example of cleaving induced strain with unobstructed grooves in accordance with some embodiments of the technology described herein.

FIG. 5B shows a second example of cleaving induced strain with unobstructed grooves at the exit facet, in accordance with some embodiments of the technology described herein.

### DETAILED DESCRIPTION

The inventors have developed technology to facilitate improved performance of broad area lasers and improved wire bonding configurations, which are described herein. As an example, broad area lasers include a waveguide ridge positioned on a semiconductor between adjacent grooves. The inclusion of horizontal ridges to transect the grooves at the exit facet of the laser and/or horizontal ridges placed along the length of the cavity to connect the semiconductor waveguide ridge with the adjoining substrate may improve the power output of the broad area semiconductor laser.

Semiconductor high-power, broad-area lasers are formed from layered semiconductor structures which typically include one or more active layers, separated by tunneling junctions, and a number of semiconductor layers for creating reflections back and forth through the active layer(s) for providing stimulated emission and laser emission. To shape the profile of the laser emission, additional structures may be formed in or above the layered semiconductor structure. For example, an effective design incorporates a waveguide ridge spanning the length of the laser cavity. The waveguide ridge may be bound by grooves positioned on opposing sides of the ridge. The grooves may be configured as two deep, parallel grooves that vertically cut through the thick laser epitaxy to confine the laser light, as well as the injected current and carriers, in the waveguide ridge. Along the length of the laser, the cavity is confined by the cleaved front and back facets. In this way, the ridge may act as a waveguide for optical modes resonating within the laser. When carriers are injected into active layers within the layered semiconductor structure, the resulting light will resonate within the waveguide, and the laser emission profile will depend upon the modes supported by the waveguide.

The inventors have recognized and appreciated that existing designs for high-power, broad-area lasers may make electrical connection to the waveguide ridge difficult. One solution to providing electrical contacts for the injection of carriers into the waveguide ridge is to planarize the grooves by depositing a lithographically defined polymer that can support a thin layer of metal such that the thin layer of metal electrically couples the waveguide ridge top metal contact to a wire bonding pad, separated from the waveguide ridge by the groove. Another solution to providing electrical contacts for the injection of carriers into the waveguide ridge is to deposit a thin layer of metal to conformally coat the groove slopes (electrically isolated with a thin dielectric passivation) and provide the necessary electrical connection between the laser and the wire bonding pad. These connections can be made as wide as the separation between the laser's front and back facets (e.g., approximately 600 microns) or can be made to be localized and form narrow lateral vias (e.g., approximately 50 microns). Yet another solution is to place the wire bond on an empty portion of the substrate, separated from the waveguide ridge by a groove and to use a conformal metal coating to coat the groove sidewalls and to electrically couple the waveguide ridge to the wire bond. However, fabricating conformal metal coatings spanning the length of the waveguide ridge and having robust conductive channels through the groove would depend highly on the groove sidewall smoothness and would introduce complicated fabrication processes. These and other similar solutions are not easy to fabricate, and they require additional semiconductor processing and fabrication steps, which increase the fabrication cost.

The inventors have further recognized and appreciated that high-power, broad-area lasers suffer a decreased power output, due to circulating higher order optical modes. For example, high order optical modes may reflect off the laser output facet at a high angle, such that little to no light of the optical mode escapes through the output facet, such as when the reflection experiences total internal reflection.

Accordingly, the inventors have developed high-power, broad-area lasers that include lateral ridges which extend through the grooves, joining the waveguide ridge to the adjacent substrate. In some embodiments, the lateral ridges are formed from a same material as the cross-section of the waveguide ridge, such that the refractive indices of the two structures are approximately equal. Accordingly, the semiconductor epitaxial stack, rather than a separately deposited polymer, is used to support the metal trace for electrically coupling the waveguide ridge to the wire bond pad. As an example, the lateral ridges at the end facets of the laser cavity effectively cap the grooves adjacent to the waveguide ridge. Additionally or alternatively, lateral ridges along the length of the waveguide ridge effectively break the continuous groove in the semiconductor substrate on one or both sides of the ridge of the laser into two or more shorter segments separated by the lateral ridges.

Aspects of the present lasers provide the advantage of not introducing additional processing steps, beyond those required to fabricate the waveguide ridge. For example, the inclusion of a metal layer on one or more of the lateral ridges and on the wire bonding pads may be separated from the semiconductor by a dielectric layer, preventing unwanted current injection into the adjacent semiconductor layers or the semiconductor substrate and decreasing or eliminating the electro-optical activity of the device. The dielectric layer is fabricated as part of the fabrication of the waveguide ridge and therefore does not introduce additional processing steps. Furthermore, the lateral ridges should not be made to be as wide relative to the waveguide ridges length because doing so would increase leakage of carriers from the waveguide ridge into adjacent epitaxial layers or into the substrate. Rather, the lateral ridges should be narrow, and the number of lateral ridges should be limited to limit the lateral leakage of light and lateral diffusion of carriers from the waveguide ridge. The incorporation of lateral ridges provides for wire bonding on a portion of the substrate adjacent to the waveguide ridge, with a minimal penalty in the electro-optic performance of the laser. Wire bonding to a metal adjacent to the waveguide ridge, rather than directly to the waveguide ridge, provides advantages by reducing wire bonding force to the waveguide ridge and instead distributes the strain over a wire bonding pad external to the waveguide ridge.

Relative to lateral ridges formed from a polymer material, lateral ridges formed from a same material as the waveguide ridge provide for effectively extracting light from the waveguide ridge to couple out through the output facet. Additionally, aspects of the present disclosure provide for suppression of some higher order optical modes resulting in an increased device efficiency and optical power output. For example, the inclusion of lateral ridges transecting the grooves on either side of the waveguide ridge can reduce or eliminate the trapped circulating optical modes that can significantly reduce or totally extinguish the power of the emitted light. As an added benefit, the filtering of the higher-order optical modes, the slow-axis far field profile may be improved. The suppression of higher-order modes may be achieved with or without the deposition of a metal trace layer over the lateral ridges, when the lateral ridges interrupt the continuity of the groove adjacent to the waveguide ridge. When the lateral ridges are placed at the beginning or ending of the laser cavity (e.g., at the laser facets) they keep the grooves away from the cleaved interface and could potentially improve the quality of the cleaved surface. Lateral ridges placed at the exit facet of the laser cavity provide a lateral path for heat dissipation thereby reducing the local facet temperature and potentially improving the facet robustness to high optical intensity. Accordingly, the placement of the lateral ridge at the exit facet may improve the catastrophic optical damage (COD) level.

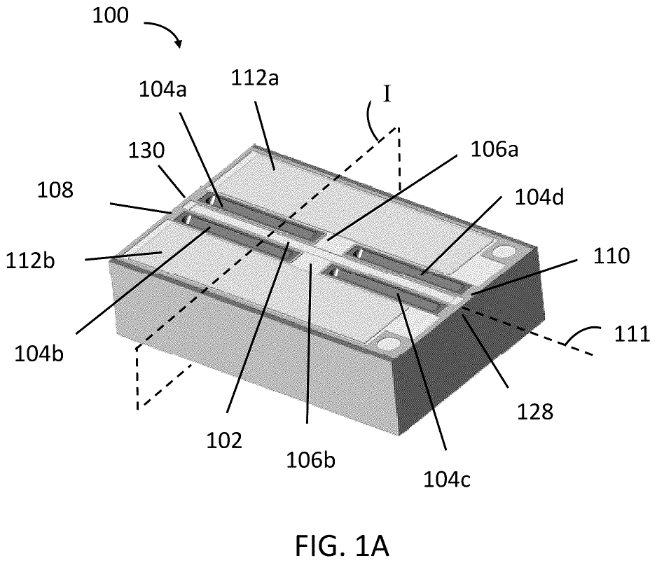

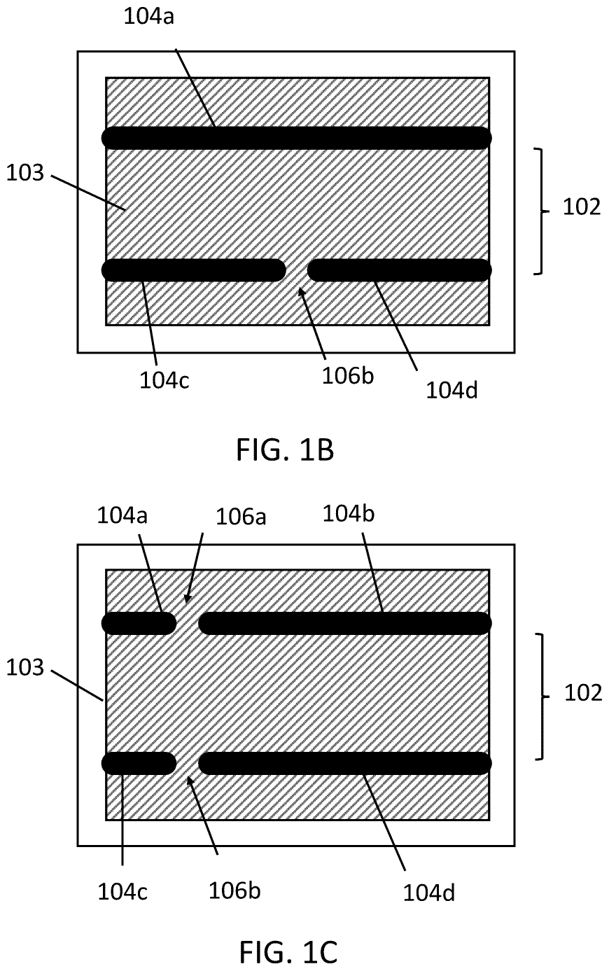

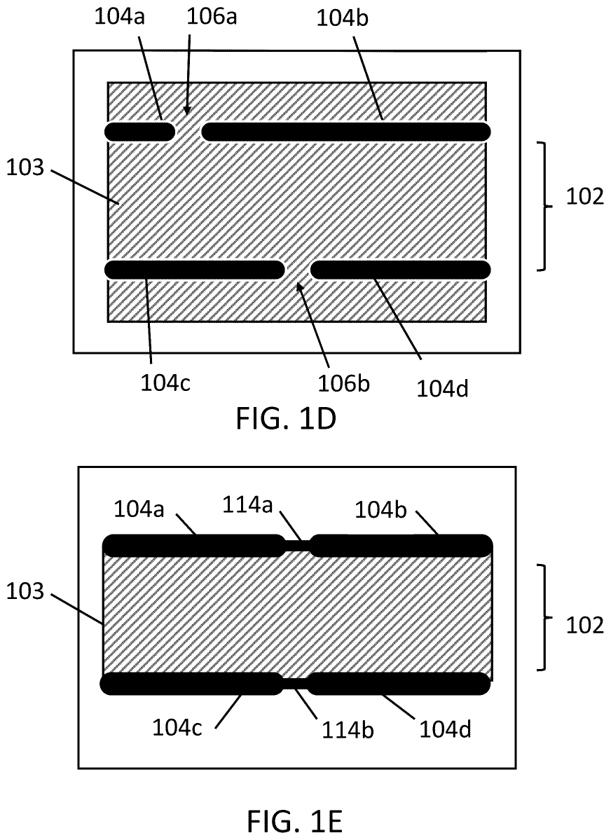

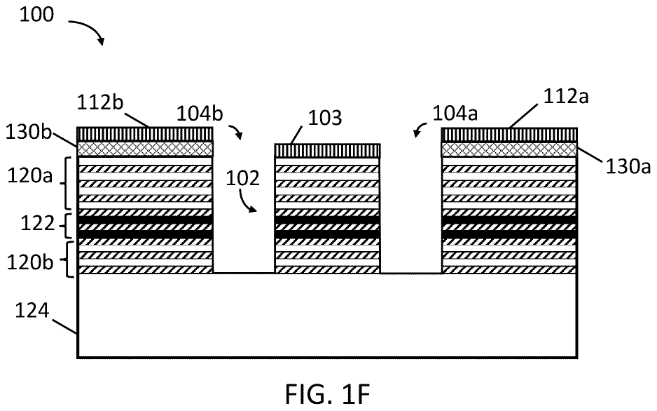

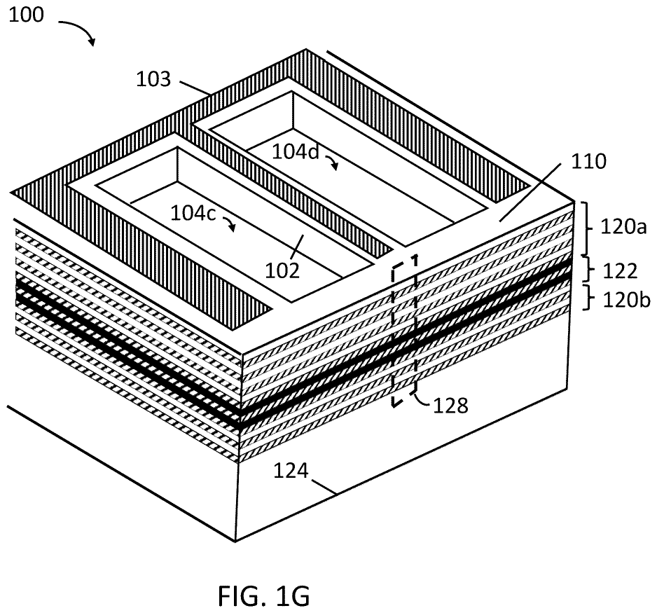

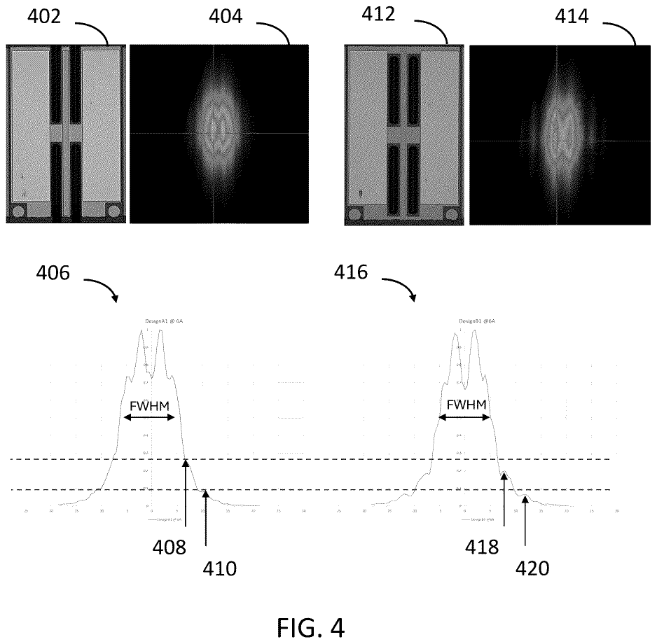

FIG. 1A shows an example semiconductor laser with interrupted grooves, in accordance with some embodiments of the technology described herein. As shown in the example of FIG. 1A, semiconductor laser 100 includes a waveguide ridge 102 extends along the transverse length of the semiconductor laser between the end facets 128 and 130. Grooves 104a, 104b, 104c, and 104d are positioned on either side of waveguide ridge 102. The grooves are transected by lateral ridge portions 106a and 106b near the center of the waveguide ridge, 108 at the end facet 130, and lateral ridge 110 at the end facet 128. Lateral ridge portion 106a interrupts grooves 104a and 104b, and lateral ridge portion 106b interrupts grooves 104b and 104c. Dashed line 111 represents the optical axis of the semiconductor laser. Optical emission from the semiconductor laser is coupled out of the waveguide ridge through the end facet. The angle of emission depends on the optical mode of, with higher order modes emitting at an angle between the optical axis and the plane of the end facet and lower order modes emitting approximately along the optical axis. An example of this improvement is provided in the far-field profiles of FIG. 4, discussed below.

In the illustrated example, the facets 128 and 130 are located on the cleaved edge of semiconductor laser 100. Accordingly, facets 128 and 130 are the specific portions of the cleaved edge that are used for laser emission. The lateral edges are also disposed at the cleaving interface, in the example of FIG. 1A, the lateral ridges 108 and 110 are at respectively end facets and separate the grooves from the cleaving interface.

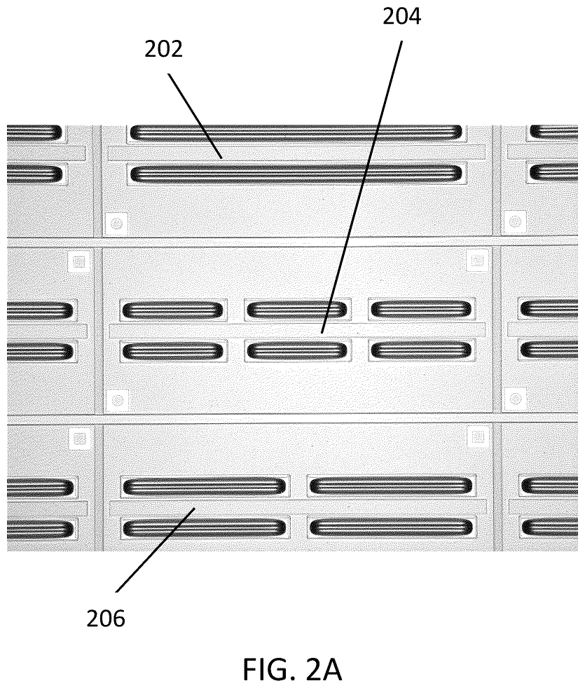

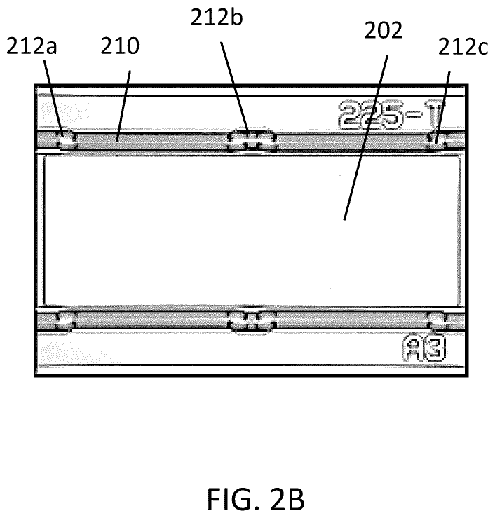

The lateral ridge portions 106a and 106b separate groove 104a from 104d and groove 104b from 104c. In some embodiments, additional lateral ridges may be included to further divide the four grooves shown in FIG. 1A into a greater number of smaller grooves. In some embodiments, the center lateral ridge portions 106a and 106b may be replaced by two central lateral ridges that are configured to divide the grooves into three respective grooves on each side of the central ridge, as discussed further below in connection with FIG. 2A.

Current injection into the waveguide ridge is facilitated by a metal layer deposited on the waveguide ridge. As shown in the example of FIG. 1A, a metal layer is deposited on top of the waveguide ridge and extends the length of the waveguide ridge between the front and back facets. To provide electrical conductivity between the metal layer on the waveguide ridge 102 and the wire bonding pad 112a and 112b, metal traces are deposited on top of the center lateral ridge portions 106a and 106b, respectively. The center lateral ridge further includes an insulating semiconductor layer such as silicon nitride or silicon oxide to electrically insulate the lateral ridge from the metal trace.

In some embodiments, all the lateral ridges 108, 110, 106a, and 106b may include a metal trace for electrically coupling the waveguide ridge to the wire bonding pads 112a and 112b. In some embodiments, only a central lateral ridge portions 106a and 106b, or asymmetric central lateral ridges include a metal trace for electrically coupling the waveguide ridge to the wire bonding pads 112a and 112b. In the illustrated example of FIG. 1A, the lateral traces at the front facet and back facet do not include metal traces. Even without the metal traces on the lateral traces at the front facet and back facet, the lateral traces may still include an insulating semiconductor layer, as discussed further below in connection with FIG. 1F.

In some embodiments, the number of active layers may be as few as one active layer or as many as 20 active layers. For example, the number of active layers may be between 2 and 16 active layers, between 2 and 10, or between 4 and 10 active layers.

Although the illustrated example of FIG. 1A shows lateral ridges 106a and 106b symmetrically arranged on either side of waveguide ridge 102, the lateral ridges may also be arranged asymmetrically, as aspects of the technology described herein are not limited in this regard.

FIG. 1B shows a top-down schematic of an asymmetric ridge configuration, in accordance with some embodiments of the technology described herein. Relative to the example shown in FIG. 1A, the example in FIG. 1B only interrupts a groove on one side of the waveguide ridge. Lateral ridge 106b interrupts grooves 104c and 104d while groove 104a is continuous on the other side of the waveguide ridge.

FIG. 1C shows a top-down schematic of a second asymmetric ridge configuration, in accordance with some embodiments of the technology described herein. Relative to the example shown in FIG. 1A, the example in FIG. 1C does not center the lateral ridges 106a and 106b. Accordingly, groove 104a and 104c are shorter than grooves 104b and 104d.

FIG. 1D shows a top-down schematic of a third asymmetric ridge configuration, in accordance with some embodiments of the technology described herein. The example in FIG. 1D is both asymmetric in the placement of the lateral ridge along the length and asymmetric in the placement of the lateral ridges on opposing sides of the waveguide ridge.

FIG. 1E shows a top-down schematic of a width-modulated groove, in accordance with some embodiments of the technology described herein. Relative to the example shown in FIG. 1A, the example in FIG. 1E does not include lateral ridges that seal the grooves. Rather, the lateral ridges are configured to only partially close/narrow the grooves. The narrowing of the grooves modulates the width of the groove along its length. As a result, the narrowed groove modulates the modes resonating within the cavity. For example, the width modulation may discriminate against circulating modes, thus improving the optical power of the emitted light, as described herein. Similar to the lateral ridges that seal the grooves, the width modulation also improves slow-axis far field profile of the emitted light.

In the illustrated example, narrow portions 114a and 114b modulate the width along the grooves such that wide portion 114a is separated from wide portion 114b by the narrow portion 114a, and wide portion 114c is separated from wide portion 114d by narrow portion 114b. Although the illustrated example is a symmetric configuration of the narrow portions 114a and 114b, the narrow portions may be arranged asymmetrically, in the same manner as discussed above in connection with the placement of lateral ridges in FIGS. 1A-1D.

When no lateral ridges are included, wire bonding may be done directly to the metal contact 103 atop the waveguide ridge. However, due to the continuity of the grooves with modulated width along the length of the waveguide ridge, the grooves may keep adjacent lasers disposed on a common substrate electrically isolated from each other. Accordingly, the modulated width grooves may support a higher density in some configurations while maintaining the power output benefits of higher order mode suppression.

Although the examples in FIGS. 1A-1E use a single lateral ridge configuration, additional lateral ridges may also be used, as aspects of the technology described herein are not limited in this respect.

FIG. 1F shows a cross-sectional view of semiconductor laser 100 through plane I, shown in FIG. 1A. The cross-sectional view shows the epitaxial layers and quantum wells stacked on substrate 124. The stack of epitaxial layers includes alternating layers of two materials having different refractive indices.

The cross-sectional view includes two stacks of epitaxial layers, 120a and 120b with quantum well structures 122 between the two epitaxial layers. In the example of FIG. 1F, epitaxial stack 120b is disposed on substrate 124, with quantum well structures 122 disposed on epitaxial layers 120b. Epitaxial stack 120a is disposed on the quantum well structures 122. The illustrated example includes two quantum wells with a spacing layer between them configured as a single-active laser. Metal contact 103 is disposed on top of epitaxial stack 120a. Although illustrated with two quantum wells, any suitable number of quantum wells may be disposed between the epitaxial stacks, as described herein. Additionally, although shown as a single-active layers, multi-active-lasers may be used that include multiple active regions separated by a tunneling junction. For example, the structure shown in FIG. 1F for layers of the single-active (120a, 122, and 120b), may be repeated as an additional active stack of layers disposed above layers 120a and below layer 130b and may be separated from the 120a by a tunneling junction. As another example, the second active stack of layers may be disposed below layer 120b and above substrate 124 and may be separated from 120b by a tunneling junction.

Two grooves 104a and 104b extend through the epitaxial stacks to, at least partially, isolate waveguide ridge 102 in a lateral direction. The lateral direction corresponds to the width of waveguide ridge 102 that is bounded by grooves 104a and 104b, shown in FIG. 1F. The isolation of waveguide ridge 102, at least partially, confines lower level optical modes to the waveguide ridge 102. These lower level optical modes will propagate along the waveguide ridge 102 in a direction perpendicular to the cross-sectional view, into and out of the page.

In the example of FIG. 1F, the grooves 104a and 104b extend fully through the epitaxial stacks to the substrate 124. However, the depth of the grooves may not extend all the way to substrate in all embodiments. In some embodiments, the grooves may extend only partially through the epitaxial layers. In some embodiments, the grooves may further extend into the substrate 124.

In some embodiments, grooves 104a and 104b may be coated with a semiconductor oxide or filled with other filling material, as aspects of the technology described herein are not limited in this respect.

An insulating layer 130a and 130b may is deposited on top of the layer stack 120a of the semiconductor laser. The insulating layers 130a and 130b insulate the epitaxial layer stacks from electrodes 112a and 112b, respectively. Additionally, in some embodiments, conductive layers, such as metalized layers, may be included as one of the lower layers of the layer stack to facilitate current injection through the active layers to provide for electrical injection of carriers. During current injection, a voltage difference is applied to electrodes on opposing sides of the active layers such that carriers are injected into the multilayer stacks 120a and 120b of the semiconductor laser. For example, electrode 112a may be electrically coupled to the metalized layer deposited on top of the waveguide ridge, while electrode 112b may be connected to an embedded metalized layer through conductive vias. As another example, metal contact 103 may be configured as the anode electrode to inject holes in the quantum well structures 122. A cathode electrode that injects electrons into the quantum wells through layers 120b may be disposed on the bottom surface of substrate 124. Accordingly, the substrate 124 may be n-doped. Metal contact 103 may be connected with lateral ridges to either or both 112b and 112a, for the anode connection. For the cathode electrode, connections may be made to the bottom surface of the substrate either through internal layers that provide connections from a top surface of the package to the cathode electrode or through external connections to the bottom of substrate 124.

FIG. 1G shows a perspective view of lateral ridge 110 of semiconductor laser 100, in accordance with some embodiments of the technology described herein. The perspective view shows epitaxial stacks 120a and 120b with quantum wells 122 disposed between the two stacks. Metal contact 103 is shown on the top surface of the semiconductor laser and grooves 104c and 104d are shown extending down in the direction of substrate 124 from the top surface of the semiconductor laser 100.

FIG. 1G shows the end facet 128 of semiconductor laser 100. End facet 128 corresponds to the cleaved surface adjacent to the waveguide ridge 102. The opposite side of waveguide ridge 126, that is adjacent to lateral ridge 110, includes a second end facet configured substantially the same way as end facet 128.

FIG. 2A shows a top-down view of a wafer with examples of semiconductor lasers with interrupted grooves, in accordance with some embodiments of the technology described herein. The example semiconductor lasers shown in FIG. 2A, include semiconductor lasers with different numbers of lateral ridges. Semiconductor laser 202 includes lateral ridges at the front and back of the laser substrate, such that when the semiconductor laser is cleaved, the grooves do not extend to the front and back facets of the semiconductor laser. Semiconductor laser 204 includes central lateral ridges which divide the grooves into three approximately equally sized grooves on each side of the waveguide ridge in addition to the grooves at the front and back of the laser substrate. Semiconductor laser 206 includes a single central ridge which divides the grooves into two approximately equally sized grooves on each side of the waveguide ridge in addition to the grooves at the front and the back of the laser substrate. In each of the illustrated examples of FIG. 2A, the lateral ridges are each approximately 50 microns wide and the laser metal-semiconductor contacts are approximately 32 microns wide. However, other dimensions may be used as aspects of the technology described herein are not limited in this respect.

Although the embodiments in FIG. 2A show symmetrically arranged horizontal ridges on each side of the waveguide ridge, in other embodiments, the ridges may be arranged asymmetrically. For example, the ridges on one side of the waveguide ridge may not be aligned with ridges on the other side of the waveguide ridge and/or one side of the waveguide ridge may have a different number of ridges than the other side of the waveguide ridge, as discussed above.

FIG. 2B shows a top down view of a wafer with modulated grooves, in accordance with some embodiments of the technology described herein. Semiconductor laser 202 includes modulated grooves 210 having with narrow portions 212a, 212b, and 212c.

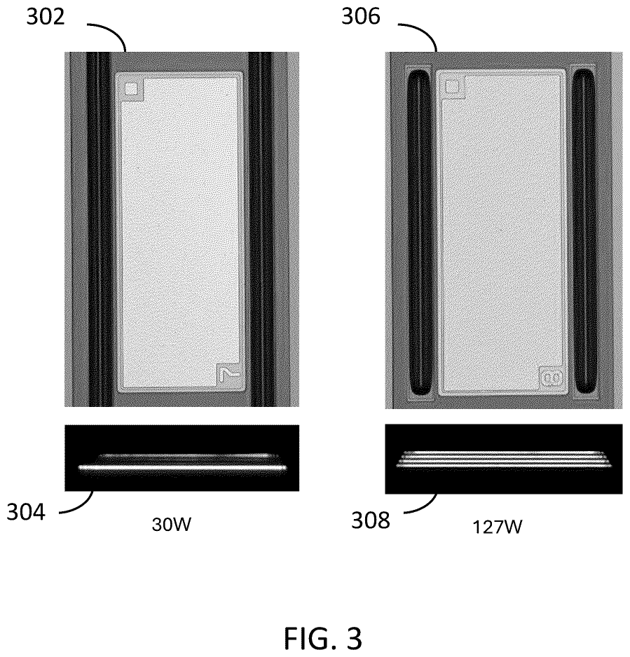

FIG. 3 shows an example of the power output enhancement induced by horizontal ridges across the grooves at the exit facet, in accordance with some embodiments of the technology described herein. In each of the semiconductor lasers shown in top-down views 302 and 306, the lasers include four laser strips, correspond to four laser actives. In the top-down view 302 of a first semiconductor laser, the illustrated laser does not include lateral ridges. Accordingly, the grooves on either side of the central ridge extend to the exit facet of the laser.

Panel 304 shows only a bottom laser strip of the first semiconductor laser, out of the four strips, as being active with significant optical power. The injected carriers in the other three active strips are consumed by the trapped circulating modes. Accordingly, the power output is approximately 30 W from the first semiconductor laser. In contrast, as shown in panel 308, the laser with the lateral ridge at the facets emits 127 W of optical power. With a suppression of some of the higher order modes, namely circulating modes, all four of the active strips emit light.

The inventors have recognized and appreciated that the circulating modes can decrease the output power of the laser because they may not exit the cavity, but they compete with other cavity modes for gain. In some embodiments, the low order circulating modes may still exit the cavity at a high angle, but the coupling of those modes out of the cavity is not as efficient as that of the non-circulating modes. Accordingly, the suppression of circulating modes reduces the competition between circulating and non-circulating modes for gain, and by extension, output power of the laser.

In the top-down view 306 of a second semiconductor laser, the illustrated laser does include lateral ridges. Accordingly, unlike in the first semiconductor laser, the grooves in the second semiconductor laser do not extend to the exit facet of the laser.

Although the illustrated example of FIG. 3 includes quad lasers (e.g., four laser strips/actives), other multi-active laser configurations may be used, as aspects of the technology described herein are not limited in this respect. For example, other multi-active laser configurations such as double lasers (e.g., two laser strips), triple lasers (e.g., three laser strips), penta lasers (e.g., five laser strips), or even larger numbers of laser strips may be used.

The inventors have recognized and appreciated that the effect of circulating modes is more pronounced for lasers with a small length-to-width aspect ratio of ˜3 or less. Therefore, the circulating mode suppression may be larger in 9 millimeter-wide lasers relative to 3 millimeter-wide lasers.

In some embodiments, grooves are wet-etched rather than dry etched. The process of wet etching can create local non-smoothness of the groove sidewalls as well as a local increase in the sidewall verticality, which promotes formation of circulating modes. Therefore, the suppression of circulating modes may be larger in wet-etched grooves.

FIG. 4 shows an example of changes to the beam profile for a laser by including horizontal ridges across the grooves at the exit facet, in accordance with some embodiments of the technology described herein. The two lasers shown in panel 402 and 412 respectively each include 20-micron wide metal-semiconductor contacts. Panel 402 shows a top-down view of a first laser without lateral ridges. Panel 404 shows a corresponding 2D far-field profile of the light produced by the first laser shown in panel 402. Panel 406 shows a cross section taken through the 2D far-field profile 404. Panel 412 shows a top-down view of a second laser with lateral ridges. Panel 414 shows a corresponding far-field profile of the light produced by the second laser shown in panel 412. Panel 416 shows a cross section taken through the 2D far-field profile 414.

Comparing the beam profiles for the first laser shown in panel 402 with the second laser shown in panel 412, the inclusion of lateral ridges at the exit facets can be seen to remove higher order modes by the field profile at point 418 relative to point 408 and further at point 420 relative to point 410.

In addition to suppressing higher order modes, the inclusion of lateral ridges at the end facets reduce the full width half max of the slow-axis far field profile from 12 degrees (without lateral ridges at end facets) to 10.1 degrees (with lateral ridges at end facets).

In some embodiments, the laser described herein generated pulsed broad area output. The lasers may operate as nanosecond lasers. For example, producing pulses as short as 1 to 5 nanoseconds, 1 to 10 nanoseconds, or 1-100 nanoseconds when operated at a low duty cycle, such as 0.01% to 0.5%. Relative to a continuous-wave laser, these pulses may provide up to ten times more power.

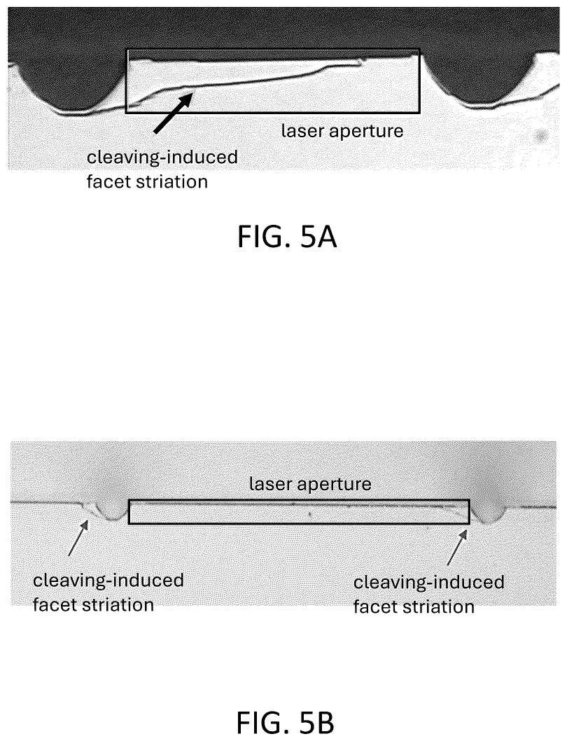

FIG. 5A shows an example of cleaving induced strain with unobstructed grooves. As shown in FIG. 5A, the cleaving-induced strains extend to across the laser aperture (indicated by the boxed region).

FIG. 5B shows a second example of cleaving induced strain with unobstructed grooves. Interrupted grooves at the end facet may improve the quality of the cleaved facet, preventing or reducing the size of defects created by the cleaving induced strain.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

The phrase “and/or,” as used herein in the specification and in the claims, should be understood to mean “either or both,” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

The indefinite articles “a” and “an,” as used herein in the specification and in the claims, unless clearly indicated to the contrary, should be understood to mean “at least one.”

As used herein in the specification and in the claims, the phrase, “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently, “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “substantially,” “approximately,” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

All definitions, as defined and used herein, should be understood to control over dictionary definitions, definitions in documents incorporated by reference, and/or ordinary meanings of the defined terms.

The word “exemplary” is used herein to mean serving as an example, instance, or illustration. Any embodiment, implementation, process, feature, etc. described herein as exemplary should therefore be understood to be an illustrative example and should not be understood to be a preferred or advantageous example unless otherwise indicated.

1. An integrated semiconductor laser comprising:
a semiconductor substrate including a plurality of semiconductor layers having a transverse axis aligned with an optical axis of the integrated semiconductor laser, the plurality of semiconductor layers including at least one active layer;
a waveguide ridge formed from the plurality of semiconductor layers and extending along the transverse axis between a front facet and a back facet of the integrated semiconductor laser;
a plurality of grooves disposed on opposing sides of the waveguide ridge, wherein the plurality of grooves is elongated along the transverse axis; and
at least one lateral ridge formed from the plurality of semiconductor layers and extending across at least one of the plurality of grooves.

2. The integrated semiconductor laser of claim 1, wherein a first lateral ridge of the at least one lateral ridge is configured at an end facet of the integrated semiconductor laser such that a surface of the end facet is smooth.

3. The integrated semiconductor laser of claim 2, wherein a second lateral ridge of the at least one lateral ridge is configured at a second end facet such that a surface on each end facet of the integrated semiconductor laser is smooth.

4. The integrated semiconductor laser of claim 1, wherein a first lateral ridge of the at least one lateral ridge is configured to intersect a middle portion of the waveguide ridge.

5. The integrated semiconductor laser of claim 4, wherein the first lateral ridge transects a first groove of the plurality of grooves on a first side of the waveguide ridge and the first lateral ridge further transects a second groove of the plurality of grooves on a second side of the waveguide ridge.

6. The integrated semiconductor laser of claim 5, wherein a second lateral ridge of the at least one lateral ridge transects the first groove, such that the first lateral ridge and second lateral ridge divide the first groove into three shorter grooves.

7. The integrated semiconductor laser of claim 4, wherein a metal trace is disposed on a top surface of the first lateral ridge, and the metal trace is separated from a top semiconductor layer of the first lateral ridge by an insulating layer.

8. The integrated semiconductor laser of claim 7, further comprising a first wire bonding pad and a second wire bonding pad, wherein the second wire bonding pad is separated from the first wire bonding pad by the waveguide ridge and the plurality of grooves.

9. The integrated semiconductor laser of claim 8, wherein the first wire bonding pad comprises a metal pad separated from a top semiconductor layer of the integrated semiconductor laser by an insulating layer.

10. The integrated semiconductor laser of claim 9, wherein the first wire bonding pad and the metal trace are further configured to inject carriers into the waveguide ridge when a current is applied to the first wire bonding pad.

11. The integrated semiconductor laser of claim 1, wherein the at least one lateral ridge is formed of a same material as that of the waveguide ridge.

12. The integrated semiconductor laser of claim 1, wherein the at least one lateral ridge is formed of a different material as that which the waveguide ridge is formed.

13. The integrated semiconductor laser of claim 1, wherein the plurality of semiconductor layers comprises additional active layers, and a total number of active layers for the integrated semiconductor laser is between 2 and 10 active layers.

14. The integrated semiconductor laser of claim 13, wherein the plurality of semiconductor layers are epitaxial layers.

15. The integrated semiconductor laser of claim 13, wherein the plurality of semiconductor layers comprises epitaxially grown semiconductor layers.

16. An integrated semiconductor laser comprising:
a semiconductor substrate including a plurality of semiconductor layers having a transverse axis aligned with an optical axis of the integrated semiconductor laser, the plurality of semiconductor layers including at least one active layer;
a waveguide ridge formed from the plurality of semiconductor layers and extending along the transverse axis between a front facet and a back facet of the integrated semiconductor laser;
a plurality of grooves disposed on opposing sides of the waveguide ridge, wherein the plurality of grooves is elongated along the transverse axis; and
at least one lateral ridge formed from the plurality of semiconductor layers and positioned between two of the plurality of grooves to connect the waveguide ridge to an outer portion of the substrate.

17. The integrated semiconductor laser of claim 16, further comprising a wire bond pad disposed on top of the waveguide ridge.

18. An integrated semiconductor laser comprising:
a semiconductor substrate including a plurality of semiconductor layers having a transverse axis aligned with an optical axis of the integrated semiconductor laser, the plurality of semiconductor layers including at least one active layer;
a waveguide ridge disposed through the plurality of semiconductor layers and extending along the transverse axis between a front facet and a back facet of the integrated semiconductor laser; and
a plurality of grooves disposed on opposing sides of the waveguide ridge, wherein the plurality of grooves is elongated along the transverse axis, and optical confinement of the waveguide ridge by the plurality of grooves varies along the transverse axis.

19. The integrated semiconductor laser of claim 18, wherein the optical confinement of the waveguide ridge by the plurality of grooves is varied by a lateral ridge capping an end of the at least one of the plurality of grooves.

20. The integrated semiconductor laser of claim 18, wherein the plurality of grooves have a first width and wherein the optical confinement of the waveguide ridge by the plurality of grooves is varied by a portion of the groove that has a width smaller than the first width.
